(19) United States
(12) Patent Application Publication
(10) Pub. No.: US 2005/0012166 A1
(43) Pub. Date: Jan. 20, 2005

(54) Image sensor

(75) Inventor: Seung-Man Choi, Osan-si (KR)

Correspondence Address: LEE & STERBA, P.C., 1101 WILSON BOULEVARD, SUITE 2000, ARLINGTON, VA, 22209, US

(73) Assignee: Samsung Electronics Co., Ltd.

(21) Appl. No.: 10/868,360

(22) Filed: Jun. 16, 2004

(30) Foreign Application Priority Data
Jun. 17, 2003 (KR) 2003-39153

(51) Int. Cl. H01L 27/14

(52) U.S. Cl. 257/414

(57) ABSTRACT

In an image sensor device, an insulating interlayer structure having an opening is formed on a semiconductor substrate on which a semiconductor device and a photodetector are formed. An electrically conductive pattern, e.g, copper, fills the opening. A diffusion preventing pattern is formed only on the electrically conductive pattern. A color filter and a lens are also provided in an optical path of the photodetector. The diffusion preventing pattern is not disposed in the optical path of the photodetector. Thus, the image sensor device having the copper pattern may be easily manufactured.

### BACKGROUND OF THE INVENTION

1. Field of the Invention

The present invention relates to an image sensor device. More particularly, the present invention relates to an image sensor device including a complementary metal-oxide-semiconductor (CMOS) image sensor (CIS).

2. Description of the Related Art

An image sensor converts optical information into electrical signals. Image sensors are generally classified as camera tubes or solid-state devices. The camera tube has been widely used in a variety of technologies, particularly for television, such as measurement, control, and recognition. There are basically two different types of solid-state image sensors: a metal-oxide-semiconductor (MOS) type and a charge-coupled device (CCD) type.

A complementary MOS image sensor (CIS) converts an optical image into an electrical signal using manufacturing technologies for the CMOS. The CIS was developed in the 1960s; however, its development has not progressed much until the 1990s, since the CIS had a lower image quality due to fixed pattern noise (FPN), a more complicated circuit structure, a lower packing density, a higher manufacturing cost and a larger size than a CCD. In the late 1990s, interest in the CIS has been revitalized due to improvements in manufacturing technologies for the CMOS and signal-processing algorithms.

Recently, owing to considerable demand for various image sensor devices such as digital still cameras and cameras incorporated into cellular phones, door phones and so on, the demand for the CIS has increased geometrically, resulting in demand for a high-powered CIS. Technologies for manufacturing the CIS having a design rule or pattern thickness of 0.18 μm have been developed. For a next generation CIS, manufacturing technologies should be compatible with a design rule or pattern thickness of 0.13 μm.

When manufacturing semiconductor devices having a pattern size less than about 0.13 μm, aluminum is no longer satisfactory as an electrical interconnection material. Copper has been suggested as an alternative to aluminum in applications where the design rule or pattern thickness is below 0.13 μm. However, copper atoms tend to diffuse into surrounding materials, such as into an interlayer dielectric layer, and can negatively impact the electrical characteristics of underlying transistors or other elements.

Therefore, in order to use copper as an interconnection material in an integrated circuit device, a diffusion barrier layer is necessary to prevent diffusion of the copper into surrounding materials. Typically, such a diffusion barrier layer is formed of SiN or SiC. However, these materials have superior light absorbance, i.e., are opaque at the wavelengths to be detected. Therefore, the presence of these materials in an optical path of a photodetector may negatively impact the performance of image devices. The presence of such material may prevent the photodetector from functioning as an image sensor when the material is not removed.

### SUMMARY OF THE INVENTION

The present invention is therefore directed to an image sensor structure and method, which substantially overcomes one or more of the problems due to the limitations and disadvantages of the related art.

It is therefore a feature of an embodiment of the present invention to provide an image sensor device having a copper electrical interconnection, e.g., having a width less than about 0.13 μm. It is another feature of an embodiment of the present invention to provide an image sensor device having an increased amount of light incident on a photodetector. It is yet another feature of an embodiment of the present invention to provide an easily manufactured image sensor.

At least one of the above and other features and advantages of the present invention may be realized by providing an image sensor device, including a substrate having a photodetector formed therein, a semiconductor device on the substrate, and a transparent insulating interlayer on the substrate. The transparent insulating interlayer has at least one opening formed therethrough corresponding to the semiconductor device. An electrically conductive pattern fills the opening. A diffusion preventing pattern is selectively formed only on the electrically conductive pattern. A color filter may be provided in an optical path of the photodetector and a lens may be formed on the color filter.

The electrically conductive pattern may be copper. The electrically conductive pattern may include a via contact including copper and a trench contact including copper, the trench contact making contact with an upper surface of the via contact.

The image sensor device may further include a lower insulation layer between the insulating interlayer and the substrate, the lower insulation layer covering the semiconductor device and a lower contact formed at a predetermined portion of the lower insulation layer to electrically contact with the semiconductor device.

The image sensor device may further include a first insulating interlayer disposed on the lower insulation layer, a first copper interconnection formed at a predetermined portion of the first insulating interlayer to electrically contact with the lower contact, and a first diffusion preventing pattern formed on the first copper interconnection. The image sensor device may further include a first barrier metal layer formed on a lower surface and a side surface of the first copper interconnection so as to prevent copper of the first copper interconnection from diffusing into the first insulating interlayer.

The image sensor device may further include a second insulating interlayer to an N-th insulating interlayer disposed on the first insulating interlayer, where N is a natural number greater than or equal to 2, a first copper interconnection to an (N−1)-th copper interconnection formed at each of predetermined portions of the second insulating interlayer to the N-th insulating interlayer, and a diffusion preventing pattern selectively formed on each of the first copper interconnection to the (N−1)-th copper interconnection. Each first copper interconnection to the (N−1)-th copper interconnection may include a via contact including copper and a trench contact including copper, the trench contact electrically contacting an upper surface of the via contact.

The image sensor device may further include a second barrier metal layer to an N-th barrier metal layer formed on lower surfaces and side surfaces of the first copper interconnection to an (N−1)-th copper interconnection, respectively, the second barrier metal layer preventing copper from being diffused from the first copper interconnection to the (N−1)-th copper interconnection into the second insulating interlayer to the N-th insulating interlayer, respectively.

The image sensor device may further include an anti-reflection coating on at least the photodetector.

The electrically conductive pattern may completely fill the opening, the diffusion preventing pattern may be formed on an upper surface of the electrically conductive pattern, and the upper surface of the electrically conductive pattern may have a height substantially identical to that of an upper surface of the insulating interlayer.

The electrically conductive pattern may fill a lower portion of the opening and the diffusion preventing pattern may fill an upper portion of the opening, thereby completely filling the opening with the electrically conductive pattern and the diffusion preventing pattern.

The diffusion preventing pattern may be a metal, e.g, tungsten or tungsten nitride. The diffusion preventing pattern may be silicon nitride. The diffusion preventing pattern may have a thickness of about 100 Å to about 500 Å.

The image sensor device may further include an upper insulation layer formed over the transparent insulating interlayer, the upper insulation layer for covering the diffusion preventing pattern. The color filter may be formed on the upper insulation layer.

At least one of the above and other features and advantages may be realized by providing a method for forming an image sensor device, including forming a photodetector in a substrate, forming a semiconductor device on the substrate, forming a transparent insulating interlayer on the substrate, the transparent insulating interlayer having at least one opening formed therethrough corresponding to the semiconductor device, filling the opening with an electrically conductive pattern, and selectively forming a diffusion preventing pattern only on the electrically conductive pattern.

The selectively forming of the diffusion preventing pattern may include providing metal on the electrically conductive pattern using an electroless plating process or using a chemical vapor deposition process. The method may further include removing a portion of the electrically conductive pattern in the opening and wherein the forming the diffusion preventing pattern includes filling the opening where the portion of the electrically conductive pattern was removed.

At least one of the above and other features and advantages of the present invention may be realized by providing an image sensor device including a substrate on which a photo diode and a semiconductor device are formed, a lower insulation layer formed over the substrate, the lower insulation layer having a lower contact electrically connected to the semiconductor device, an insulating interlayer that is transparent and formed on the lower insulation layer, the insulating interlayer having at least one opening formed therethrough, a copper pattern filling the opening so as to transmit a signal, a diffusion preventing pattern selectively formed only on the copper pattern so as to prevent diffusion of copper in the copper pattern, an upper insulation layer formed over the insulating interlayer to cover the diffusion preventing pattern, a color filter formed on the upper insulation layer, and a microlens formed on the color filter.

The copper pattern may include a via contact and a copper wiring electrically contacting with an upper surface of the via contact. The image sensor device may further include a first insulating interlayer disposed on the lower insulation layer, a first copper wiring formed at a predetermined portion of the first insulating interlayer to contact with the lower contact, and a first diffusion preventing pattern formed on the first copper wiring.

The image sensor device may further include a first barrier metal layer formed on a lower surface and a side surface of the first copper wiring so as to prevent copper from being diffused into the first insulating interlayer. The image sensor device may further include a second insulating interlayer to an N-th insulating interlayer disposed on the first insulating interlayer, where N is a natural number greater than or equal to 2, a first metal layer to an N-th metal layer formed at each of predetermined portions of the second insulating interlayer to the N-th insulating interlayer, each of the first metal layer to the N-th metal layer may have a via contact of copper and a copper wiring electrically contacting with an upper surface of the via contact, and a diffusion preventing pattern selectively formed on each of the first metal layer to the N-th metal layer. The image sensor device may further include a second barrier metal layer to an N-th barrier metal layer formed on lower surfaces and side surfaces of the first metal layer to the N-th metal layer, respectively, so as to prevent copper from being diffused into the second insulating interlayer to the N-th insulating interlayer. The image sensor device may further include a reflection preventing layer or a reflection preventing pattern disposed on the photo diode so as to enhance light absorbance of the photo diode.

The copper pattern may completely fill the opening, and the diffusion preventing pattern may be formed on an upper surface of the metal pattern, and wherein the upper surface of the metal pattern may have a height substantially identical to that of an upper surface of the insulating interlayer. The copper pattern may fill a lower portion of the opening and the diffusion preventing pattern may fill an upper portion of the opening, thereby completely filling the opening by the copper pattern and the diffusion preventing pattern.

The diffusion preventing pattern may be formed by selectively forming a metal on the copper pattern by an electroless plating process. The diffusion preventing pattern may be formed by selectively forming a metal on the copper pattern by a chemical vapor deposition process. The diffusion preventing pattern may be tungsten. The diffusion preventing pattern may be silicon nitride or tungsten nitride. The diffusion preventing pattern has a thickness from about 100 Å to about 500 Å.

### BRIEF DESCRIPTION OF THE DRAWINGS

The above and other features and advantages of the present invention will become readily apparent to those of ordinary skill in the art by reference to the following detailed description when considered in conjunction with the accompanying drawings wherein:

FIG. 1 illustrates a cross-section of an image sensor device according to an embodiment of the present invention;

FIGS. 2A to 2N illustrate cross-sections of a method of manufacturing the image sensor device illustrated in FIG. 1 according to an embodiment of the present invention;

FIG. 3 is a graph illustrating growth of a tungsten layer relative to a lower layer in accordance with an embodiment of the present invention;

FIG. 4 illustrates a cross-section of an image sensor device according to an embodiment of the present invention;

FIGS. 5A to 51 illustrate cross-sections of a method of manufacturing the image sensor device illustrated in FIG. 4 according to an embodiment of the present invention;

FIG. 6 illustrates a cross-section of an image sensor device according to an embodiment of the present invention; and

FIG. 7 illustrates a cross-section of an image sensor device according to an embodiment of the present invention.

### DETAILED DESCRIPTION OF THE INVENTION

Korean Patent Application No. 2003-39153, filed on Jun. 17, 2003, in the Korean Intellectual Property Office, and entitled: “Image Device,” is incorporated by reference herein in its entirety.

The present invention now will be described more fully hereinafter with reference to the accompanying drawings, in which embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

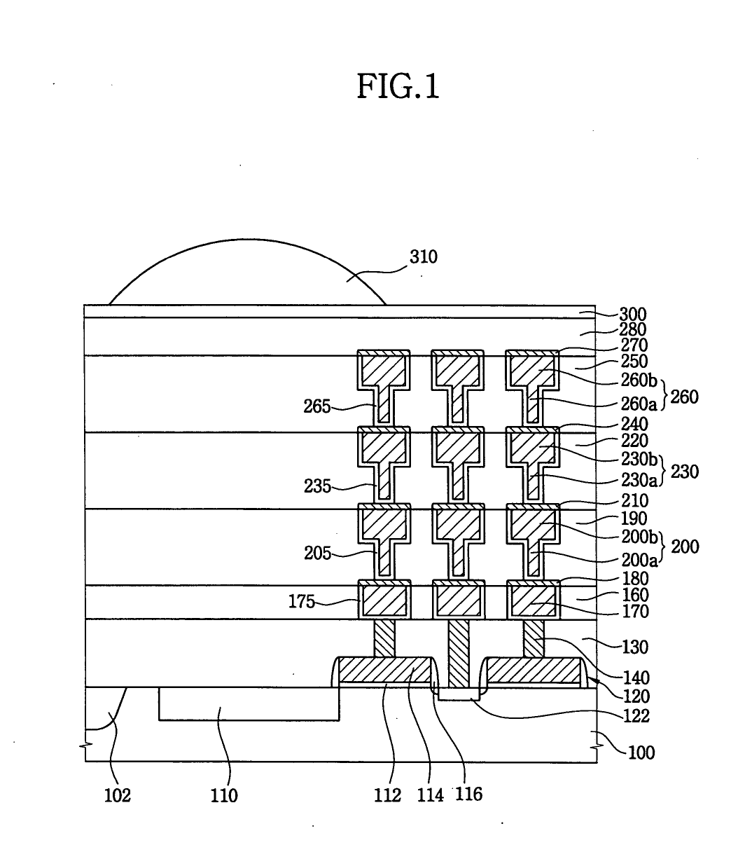

FIG. 1 illustrates a cross-section of an image sensor device according to a first embodiment of the present invention.

Referring to FIG. 1, a semiconductor substrate 100 includes an active region defined by a field oxide layer 102. A light-receiving device or photodetector 110, such as a photodiode, is formed on a surface of the active region of the semiconductor substrate 100. Further, transistors 120 serving as a switching device are formed on the semiconductor substrate 100. Each of the transistors 120 includes a gate electrode 114 and source/drain regions 122 formed between one gate electrode 114 and an adjacent gate electrode 114. A gate insulation layer 112 is formed beneath the gate electrode 114, and a spacer 116 is formed on a sidewall of the gate electrode 114.

A lower insulation layer 130 is formed on the semiconductor substrate 100 on which the transistors 120 are formed. The lower insulation layer 130 includes a transparent material such as silicon oxide. A lower contact 140 is formed through the lower insulation layer 130. The lower contact 140 is electrically connected to the source/drain regions 122 and the gate electrode 114 through the lower insulation layer 130. The lower contact 140 may include metal, for example, copper (Cu), titanium (Ti), or tungsten (W).

Although not shown in FIG. 1, if the lower contact 140 includes copper, a lower barrier metal pattern may be formed on a side surface and a lower surface of the lower contact 140 to prevent diffusion of copper. In this embodiment, the lower contact 140 includes tungsten.

A plurality of insulating interlayers is formed on the lower insulation layer 130. Each insulating interlayers has at least one opening through which an upper surface of an underlying contact, i.e., the lower contact 140, is exposed. Each of the insulating interlayers includes a transparent insulating material having a superior light transmittance, e.g., silicon oxide.

A plurality of copper interconnections is formed in the opening, and is electrically connected to the lower contact 140.

In order to prevent diffusion of copper to adjacent insulating layers, a diffusion preventing pattern is formed on each of the interconnections. The diffusion preventing pattern includes an opaque metal, and further acts as an etch stopper. The insulating interlayers and copper interconnections will be described in detail below.

A first insulating interlayer 160 having an opening through which the lower contact 140 is exposed is formed on the lower insulation layer 130. A lower copper interconnection 170 is formed in the opening and electrically connected to the lower contact 140. The first insulating interlayer 160 includes the transparent material such as silicon oxide.

A first barrier metal pattern 175 is formed on a side surface and a lower surface of the opening before forming the lower copper interconnection therein, so as to prevent the copper of the lower copper interconnection 170 from being diffused into the first insulating interlayer 160.

A first diffusion preventing pattern 180 is formed on an upper surface of the lower copper interconnection 170. The first diffusion preventing pattern 180 may be a metal, e.g., tungsten or tungsten nitride. The first diffusion preventing pattern 180 may have a thickness from about 100 Å to about 500 Å, preferably, from about 200 Å to about 300 Å.

A second insulating interlayer 190 is formed on the first insulating interlayer 160 on which the first diffusion preventing pattern 180 is formed. The second insulating interlayer 190 includes a first via that exposes the lower copper interconnection 170 and a first opening formed over the first via. A first via contact 200a and a first trench contact 200b are formed in the first via and the first opening, respectively. The first via contact 200a and the first trench contact 200b include copper. The first trench contact 200b is electrically connected to the first via contact 200a. The first via contact 200a and the first trench contact 200b will be referred to as a first copper interconnection 200 hereinafter.

A second barrier metal pattern 205 is formed between the first copper interconnection 200 and the second insulating interlayer 190, i.e., on bottom and side surfaces of the first copper interconnection 200, so as to prevent diffusion of copper in the first copper interconnection 200 into the second insulating interlayer 190. A second diffusion preventing pattern 210 is formed on an upper surface of the first trench contact 200b.

A third insulating interlayer 220 is formed on the second diffusion preventing pattern 210 and the second insulating interlayer 190. The third insulating interlayer 220 includes a second via that exposes the second diffusion preventing pattern 210 and a second opening formed over the second via. A second via contact 230a and a second trench contact 230b are formed in the second via and the second opening, respectively. The second via contact 230a and the second trench contact 230b include copper. The second trench contact 230b is electrically connected to the second via contact 230a. Hereinafter, the second via contact 230a and the second copper trench 230b will be referred to as a second copper interconnection 230.

A third barrier metal pattern 235 is formed between the second copper interconnection 230 and the third insulating interlayer 220, i.e., on bottom and side surfaces of the second copper interconnection 230, so as to prevent diffusion of copper in the second copper interconnection 230 into the third insulating interlayer 220. A third diffusion preventing pattern 240 is formed on an upper surface of the second copper interconnection 230.

A fourth insulating interlayer 250 is formed on the third diffusion preventing pattern 240 and the third insulating interlayer 220. The fourth insulating interlayer 250 includes a third via that exposes the third diffusion preventing pattern 240 and a third opening formed over the third via. A third via contact 260a and a third trench contact 260b are formed in the third via and the third opening, respectively. The third via contact 260a and the third trench contact 260b include copper. The third trench contact 260b is electrically connected to the third via contact 260a. The third via contact 260a and the third trench contact 260b will be referred to as a third copper interconnection 260 hereinafter.

A fourth barrier metal pattern 265 is formed between the third copper interconnection 260 and the fourth insulating interlayer 250, i.e., on bottom and side surfaces of the third copper interconnection 260, so as to prevent diffusion of copper in the third copper interconnection 260 into the fourth insulating interlayer 250. A fourth diffusion preventing pattern 270 is formed on an upper surface of the third copper interconnection 260.

An upper insulation layer 280 is formed on the fourth insulating interlayer 250 and the fourth diffusion preventing pattern 270. A color filter 300 is provided in an optical path of the photodetector 110, e.g., on the upper insulation layer 280. A lens 310, e.g., a microlens, corresponding to the photodector 110 is formed on the color filter 300. The lens 310 focuses light incident thereon and provides the focused light to the photodetector 110.

According to this embodiment of the present invention, the image sensor device includes a diffusion preventing pattern formed only on the upper surfaces of the copper interconnections. That is, the diffusion preventing pattern is no the optical path of the active light-sensing area, i.e., the photodetector, of the image sensor device. Thus, light to be incident on the photodetector is not blocked. As a result, light may be easily provided to the photodetector, thereby improving the performance of the image sensor device.

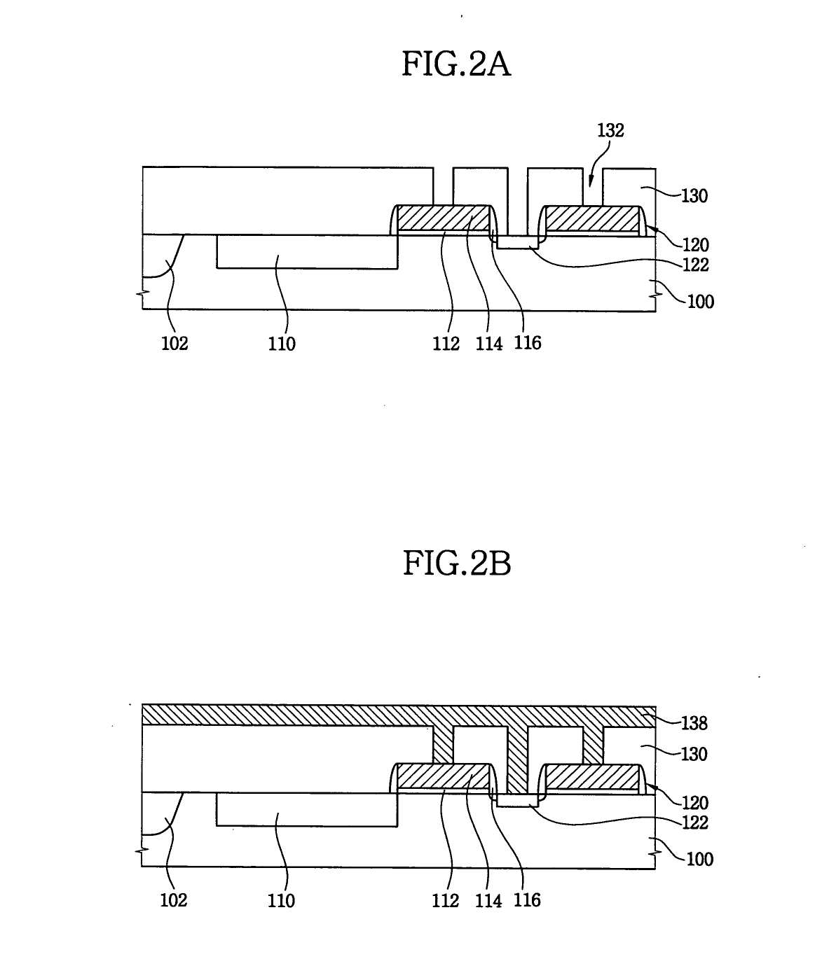

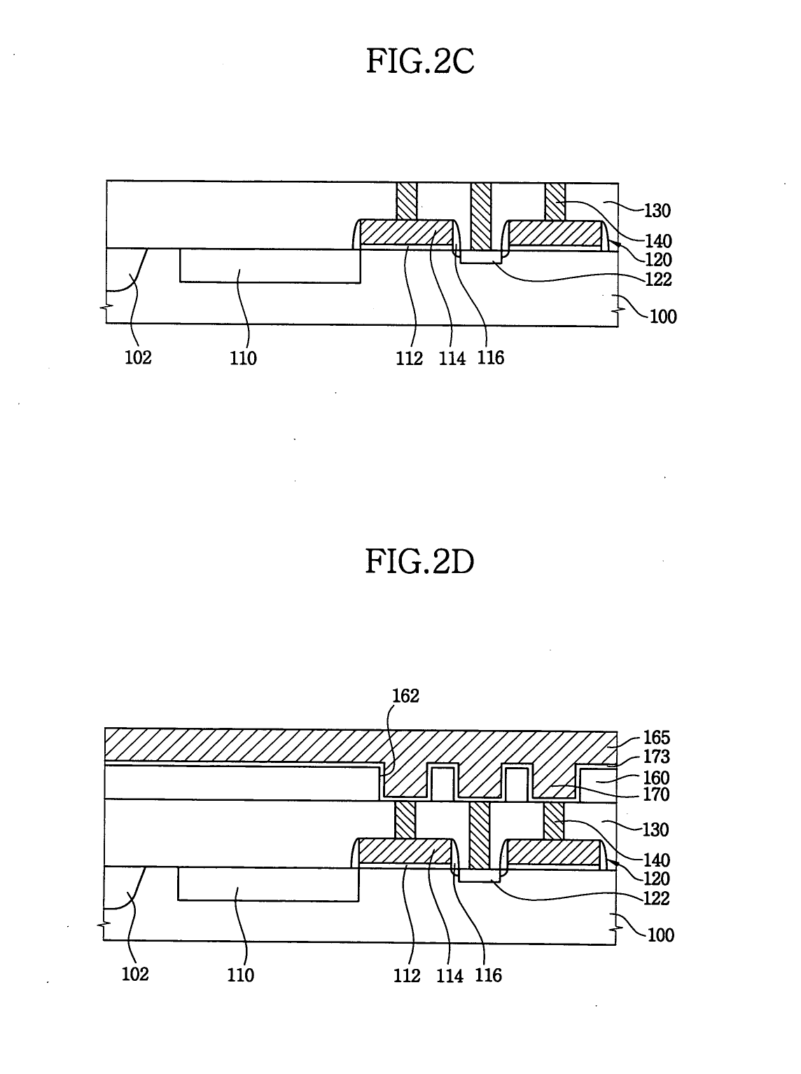

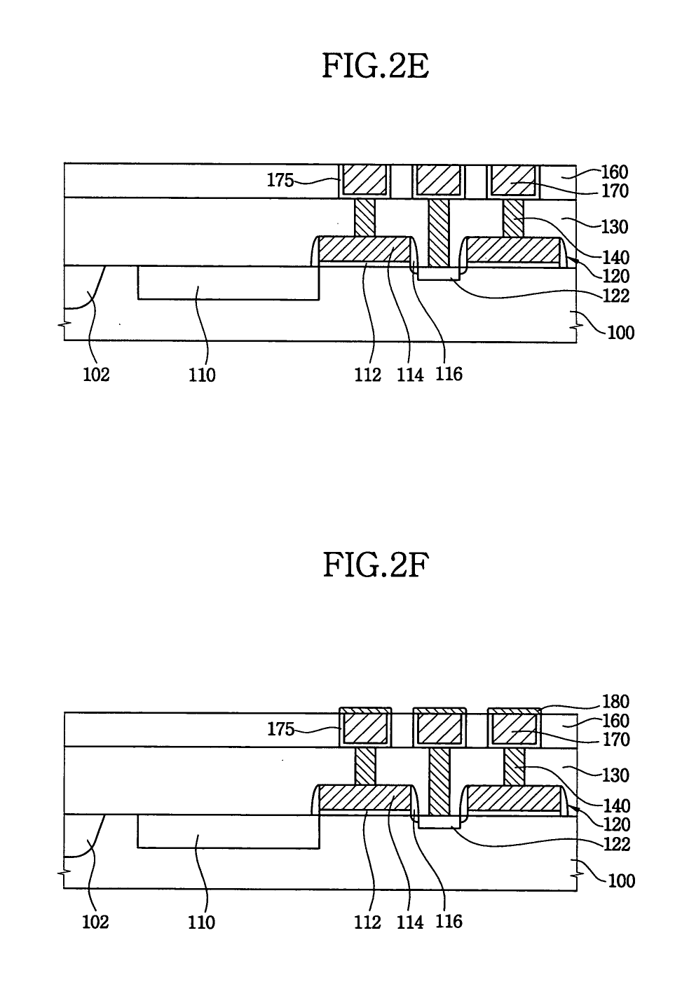

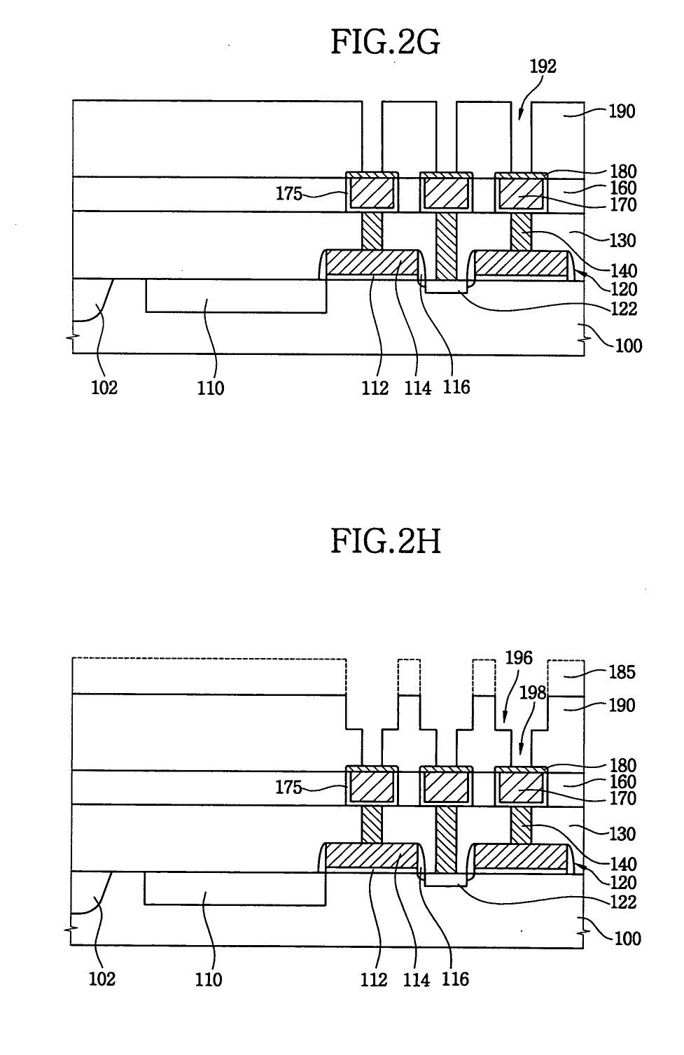

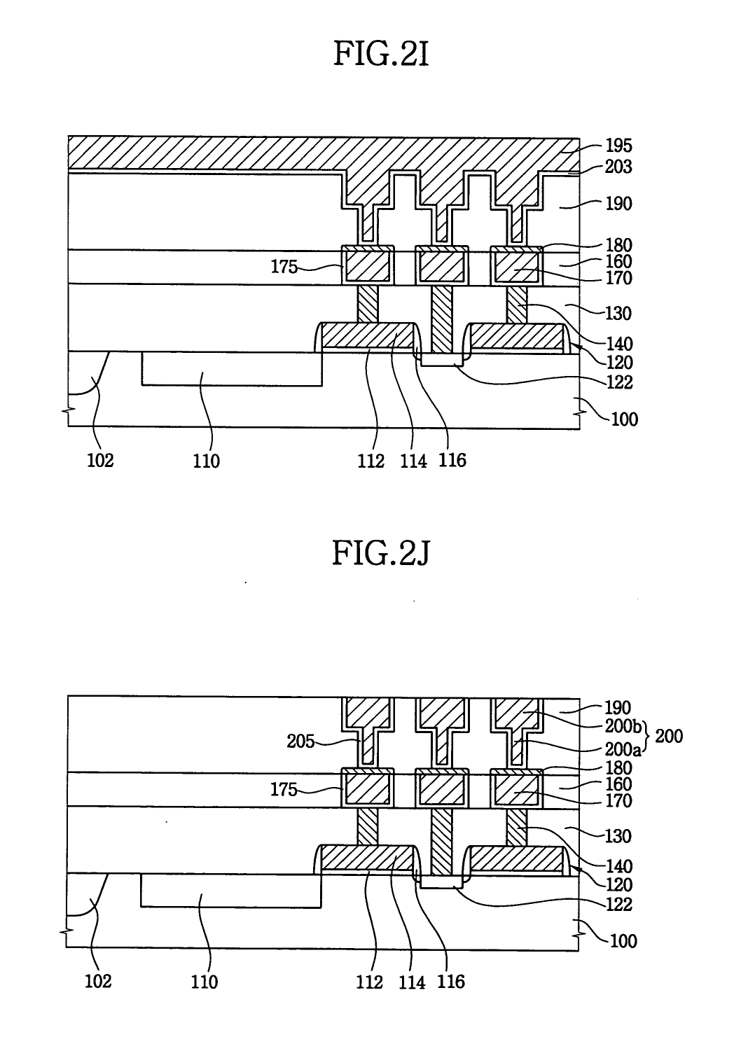

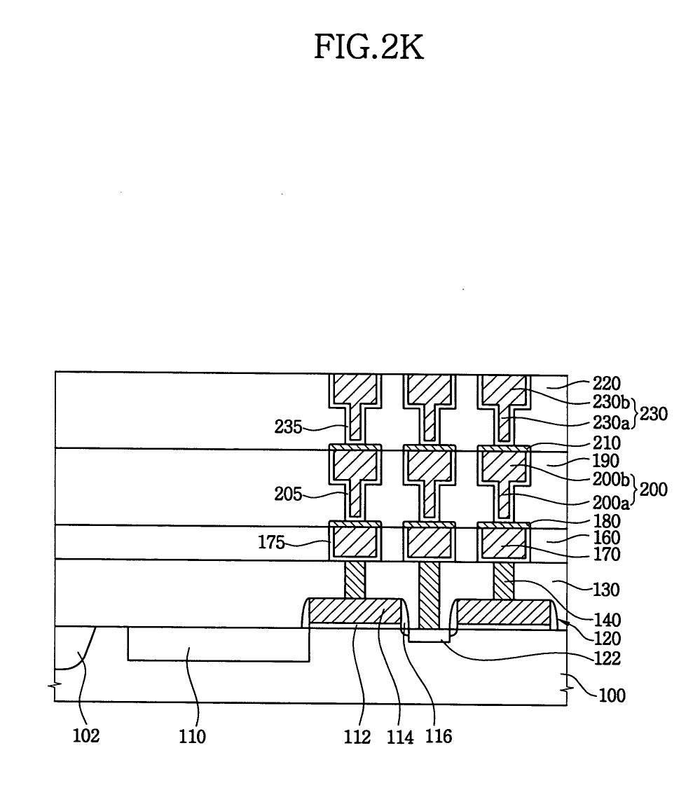

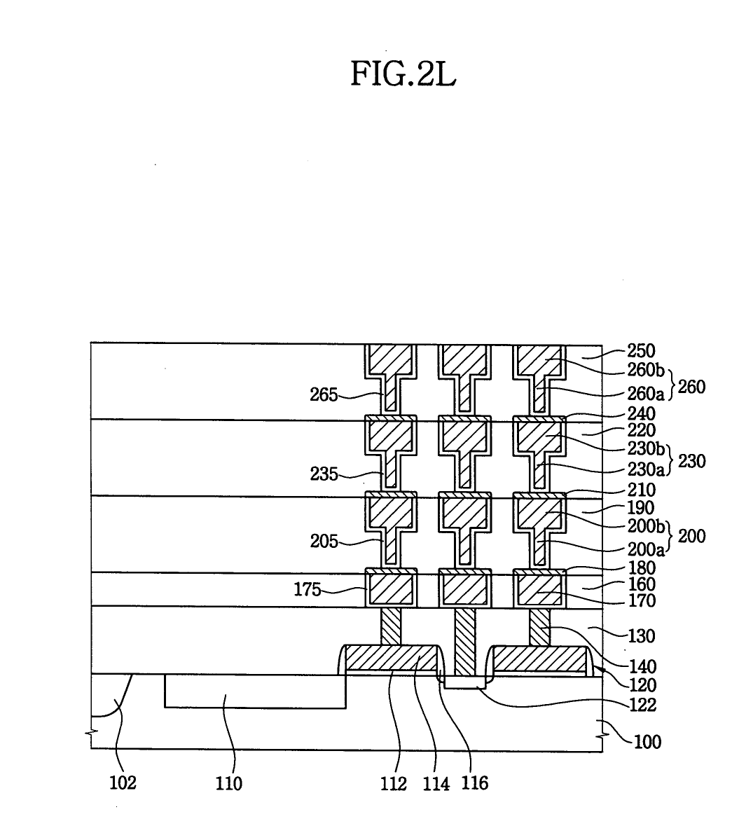

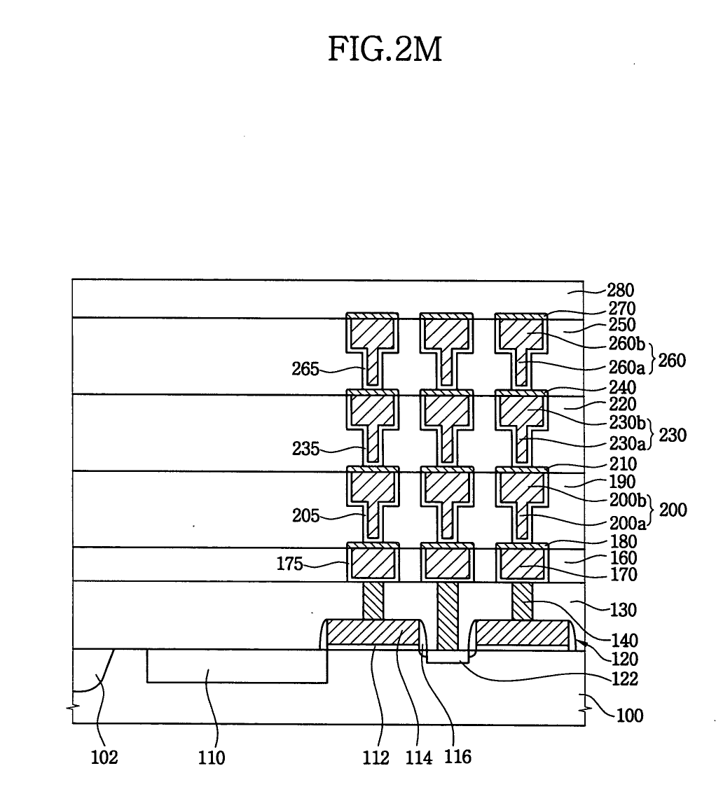

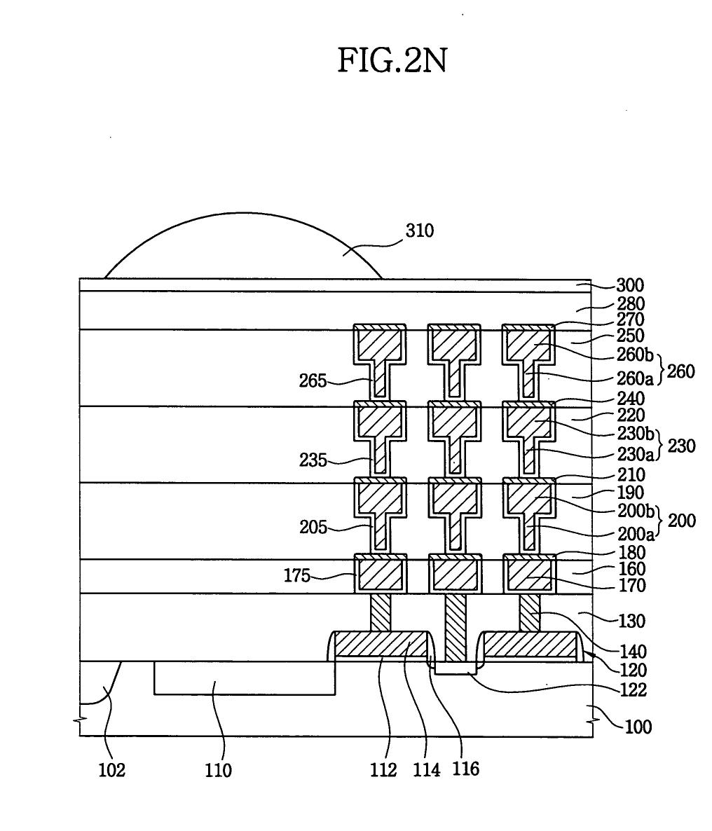

FIGS. 2A to 2N illustrate cross-sections of the image sensor device illustrated in FIG. 1 at various stages of formation for showing a method of manufacturing an image sensor device of a first embodiment of the present invention.

Referring to FIG. 2A, the field oxide 102 is formed on the semiconductor substrate 100 to define the active region. The photodetector 110 is formed on a surface of the active region, and the transistors 120 are formed on the semiconductor substrate 100, such that the photodetector 110 is electrically connected to the transistors 120.

Each of the transistors 120 includes the gate insulation layer 112 formed on the semiconductor substrate 100, the gate electrode 114 formed on the gate insulation layer 112, and source/drain regions 122 disposed between one gate electrode 114 and the adjacent gate electrode 114 and formed in the semiconductor substrate 100. The spacer 116 is formed on a sidewall of the gate electrode 114.

Then, the lower insulation layer 130 is formed over the semiconductor substrate 100 on which the transistors 120 are formed. The lower insulation layer 130 includes the transparent material such as silicon oxide.

Contact holes 132 that expose the upper surface of the source/drain regions 122 of the transistors 120 and the upper surface of the gate electrode 114 may be formed by removing a portion of the lower insulation layer 130. The removing may include etching, e.g., using photolithography.

Referring to FIG. 2B, a lower metal layer 138 is formed on the lower insulation layer 130 to fill the contact holes 132. The lower metal layer 138 may be formed using a chemical vapor deposition process or a sputtering process. The lower metal layer 138 may include copper, however, copper may be easily diffused into the semiconductor substrate 100. Thus, in this embodiment, the lower metal layer 138 includes titanium or tungsten. If the lower metal layer 138 includes copper, a barrier metal layer (not shown) must be formed on the side surface and the lower surface of the contact holes 132 before forming the lower metal layer 138.

Referring to FIG. 2C, the lower metal layer 138 is removed, e.g., by a chemical mechanical polishing process, until an upper surface of the lower insulation layer 130 is exposed, thereby forming the lower contact 140 filling the contact holes 132.

Referring to FIG. 2D, the first insulating interlayer 160 is formed on the lower contact 140 and the lower insulation layer 130. The first insulating interlayer 160 includes the transparent material such silicon oxide, and may have a thickness from about 1,000 Å to about 20,000 Å.

The first insulating interlayer 160 may be partially removed to form a lower trench 162 through which the upper surface of the lower contact 140 is exposed. This removal may include etching, e.g., using photolithography.

Then, a first barrier metal layer 173 is formed along a profile of the lower trench 162 to cover the first insulating interlayer 160. The first barrier metal layer 173 acts as a layer that prevents copper from being diffused into the first insulating interlayer 160. The first barrier metal layer 173 may include a single-layer having tantalum or tantalum nitride, or a double-layer having tantalum and tantalum nitride.

Subsequently, a first copper layer 165 is formed on the first barrier metal layer 173 so as to fill the lower trench 162. The first copper layer 165 may be formed by an electroplating process after a copper seed is formed by a sputtering method. Alternatively, the first copper layer 165 may be formed by an electroless plating process.

Referring to FIG. 2E, the first copper layer 165 and the first barrier metal layer 173 are removed until an upper surface of the first insulating interlayer 160 is exposed. The removal may include a chemical mechanical polishing process. Thus, the lower copper interconnection 170 is electrically connected to the lower contact 140.

A portion of the first barrier metal layer 173 remains on the side surface and the lower surface of the lower trench 162 and serves as the first barrier metal pattern 175. That is, copper in the lower copper interconnection 170 is not diffused into the first insulating interlayer 160 because the first barrier metal pattern 175 is formed between the lower copper interconnection 170 and the first insulating interlayer 160.

Referring to FIG. 2F, metal is selectively provided on an upper surface of the lower copper interconnection 170, e.g., by a chemical vapor deposition process, to form the first diffusion preventing pattern 180 formed on the upper surface of the lower copper interconnection 170. The first diffusion preventing pattern 180 prevents the diffusion of copper and may act as an etch stopper. To serve as an etch stopper, the first diffusion preventing pattern 180 includes metal whose etching selectivity is substantially less than that of an insulating interlayer.

According to this embodiment, the first diffusion preventing pattern 180 may include tungsten or tungsten nitride and may be formed by a chemical mechanical deposition process. The first diffusion preventing pattern 180 may have a thickness from about 100 Å to about 500 Å. More preferably, the first diffusion preventing pattern 180 may have a thickness from about 200 Å to about 300 Å. If the first diffusion preventing pattern 180 has a thickness less than about 100 Å, the first diffusion preventing pattern 180 may not act as the etch stopper. If the first diffusion preventing pattern 180 has a thickness greater than about 500 Å, the metal of this pattern may be provided on the first insulating interlayer 160 rather than just on the upper surface of the copper interconnection 170.

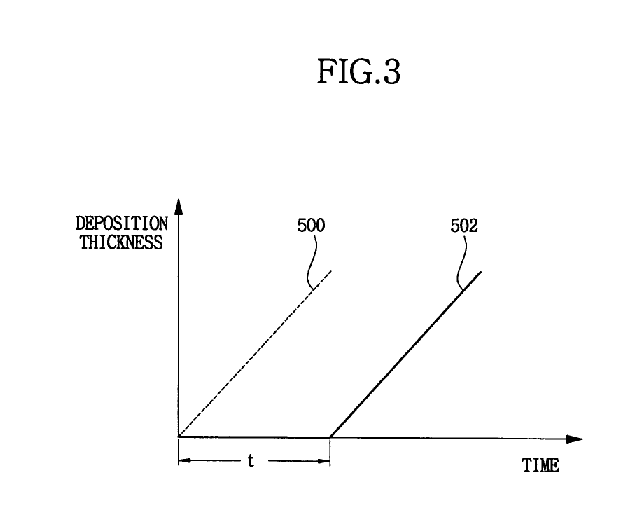

A chemical vapor deposition process that may be used with the present invention will be described in detail below in connection with FIG. 3. FIG. 3 is a graph illustrating growth of a tungsten layer relative to a lower layer in accordance with an embodiment of the present invention.

Referring to FIG. 3, in case of forming a tungsten layer by the chemical vapor deposition process, a time point at which tungsten starts to be deposited depends upon a material of a lower layer. When the layer on which the tungsten is to be deposited is a metal layer 500, the tungsten layer may be deposited on the metal layer 500 without an incubation time (t). When the layer on which the tungsten is to be deposited is an insulating material, e.g., silicon oxide layer 502, however, the tungsten layer may be deposited on the silicon oxide layer 502 only after the incubation time (t). Accordingly, when a process to deposit the tungsten layer is finished within the incubation time (t), the tungsten layer is formed only on the metal layer 500 without forming the tungsten layer on silicon oxide layer 502. That is, by controlling conditions of the chemical vapor deposition process, the tungsten layer may be selectively formed only on the metal layer 500.

When the tungsten layer is deposited at a temperature substantially higher than about 380° C., the tungsten layer may be also deposited on an insulating layer. When the tungsten layer is deposited at a temperature less than about 200° C., the tungsten layer may not be deposited even on the metal layer. Thus, when selectively forming a tungsten layer by a chemical vapor deposition process is usually performed at a temperature in a range of about 200° C. to about 350° C.

The first diffusion preventing pattern 180 has a lower light transmittance than that of silicon oxide in the insulating interlayer. However, since the first diffusion pattern 180 is formed only on the lower copper interconnection 170, the first diffusion pattern 180 is not formed on the upper surface of the first insulating interlayer 160 corresponding to the photodetector 110. That is, the first diffusion preventing pattern 180 is spaced apart from a path through which the light is provided to the photodetector 110, thereby preventing the light from being blocked.

According to this embodiment, the first diffusion preventing pattern 180 may be formed on the upper surface of the lower copper interconnection 170 by an electroless plating process. A method of selectively forming a diffusion preventing layer on a wire having copper or copper alloy by the electroless plating process is disclosed in U.S. Pat. No. 6,479,384, issued Nov. 12, 2002, to Komai et al. This electroless plating process may be employed in the present invention, as set forth below.

In the electroless plating process for use with the present invention, a catalytic metal is formed only on the upper surface of the lower copper interconnection 170 by a substitutional plating process. The catalytic metal may include metal, for example, gold (Au), nickel (Ni), cobalt (Co), platinum (Pt), or palladium (Pd), having an ionization tendency smaller than that of copper and having catalytic action. Then, the diffusion preventing pattern is formed on the catalytic metal by the electroless plating process. The first diffusion preventing pattern 180 may include a material, e.g., tungsten, that prevents diffusion of copper and acts as an etch stopper.

Referring to FIG. 2G, the second insulating interlayer 190 is formed on the first diffusion preventing pattern 180 and the first insulating interlayer 160. The second insulating interlayer 190 includes the transparent material such as silicon oxide.

The second insulating interlayer 190 is partially removed to form a first primary via 192. Thus, the first diffusion preventing pattern 180 disposed under the first primary via 192 is exposed through the first primary via 192. The removal may include etching, e.g., using photolithography.

Referring to FIG. 2H, a photoresist pattern 185 is formed on the second insulating interlayer 190 to be used in forming a trench by a photolithography process. The second insulating interlayer 190 is partially etched using the photoresist pattern 185 as an etching mask to form a first trench 196 and a first via 198. In general, the second insulating interlayer 190 is etched by a thickness from about 200 Å to about 10,000 Å.

During an etching process of the second insulating interlayer 190, the first diffusion preventing pattern 180 is exposed through the first primary via 192. However, since an etching selectivity of the second insulating interlayer 190 is substantially greater than that of the first diffusion preventing pattern 180, the first diffusion preventing pattern 180 is not etched while the second insulating interlayer 190 is etched. Thus, the lower copper interconnection 170 is not exposed during the etching process of the second insulating interlayer 190, thereby preventing the lower copper interconnection 170 from being damaged. Then, the photo resist pattern 185 is removed. Contacts electrically connected to the lower copper interconnection 170 are formed in the first trench 196 and the first via 198.

Although not shown in FIGS. 2A to 2N, a process for removing the first diffusion preventing pattern 180 may be further performed. The process for removing the first diffusion preventing pattern 180 may be omitted because the first diffusion preventing pattern 180 includes a conductive metal, and thus will not interfere with the electrical connection.

In this embodiment, a via-first damascene process that forms the first trench 196 after the first primary via 192 is formed has been described. However, the first via 198 and the first trench 196 may be formed by processes that successively forms a lower insulation layer having the first via 198, a via contact filled into the first via 198 and an upper insulating interlayer having the first trench 196 on the lower insulation layer. A trench first damascene process that forms the first via 198 after the first trench 196 is formed may be applied to the present invention.

Referring to FIG. 21, a second barrier metal layer 203 is formed along a profile of the first trench 196 and the first via 198 to cover the second insulating interlayer 190. The second barrier metal layer 203 acts as a layer that prevents the copper from being diffused into the second insulating interlayer 190 while the copper interconnection is formed. The second barrier metal layer 203 may include a single-layer having tantalum or tantalum nitride, or a double-layer having tantalum and tantalum nitride.

Subsequently, a second copper layer 195 is formed on the first barrier metal layer 203 so as to fill the first trench 196 and the first via 198. The second copper layer 195 may be formed by an electroplating process after a copper seed is formed by a sputtering process Alternatively, the second copper layer 195 may be formed by an electroless plating process, discussed above.

Referring to FIG. 2J, when the second copper layer 195 and the second barrier metal layer 203 are removed by a chemical mechanical polishing process until an upper surface of the second insulating interlayer 190 is exposed. Thus, the first copper interconnection 200 filling the first trench 196 and the first via 198 is formed. The first copper interconnection 200 includes the first via contact 200a and the first trench contact 200b.

A portion of the second barrier metal layer 203 remains on side surfaces and lower surfaces of the first trench 196 and the first via 198 to form the second barrier metal pattern 205. The second barrier metal pattern 205 prevents diffusion of the copper of the first copper interconnection 200 into the second insulating interlayer 190.

Referring to FIG. 2K, the second diffusion preventing pattern 210, the third insulating interlayer 220 and the second copper interconnection 230 are successively formed through the processes described in FIGS. 2F through 2J.

In FIG. 2K, the second diffusion preventing pattern 210 is formed only on the first copper interconnection 200 in the same manner as the first diffusion preventing pattern 180 was formed on the lower copper interconnection 170. Then, the third insulating interlayer 220 is formed on the second diffusion preventing pattern 210 and the second insulating interlayer 190. The second copper interconnection 230 is formed in a trench and a via formed through the third insulating interlayer 220. The second copper interconnection 230 is electrically connected to the second diffusion preventing pattern 210. The second copper interconnection 230 includes the second via contact 230a electrically connected to the second diffusion preventing pattern 210 and the second trench contact 230b. The third barrier metal pattern 235 is formed between the second copper interconnection 230 and the third insulating interlayer 220, i.e., on bottom and side surfaces of the second copper interconnection 230.

Referring to FIG. 2L, the third diffusion preventing pattern 240 is formed only on the second copper interconnection 200 in the same manner as the first diffusion preventing pattern 180 was formed on the lower copper interconnection 170. Then, the fourth insulating interlayer 250 is formed on the third diffusion preventing pattern 240 and the third insulating interlayer 220. The third copper interconnection 260 is formed in a trench and a via formed through the fourth insulating interlayer 250. The third copper interconnection 260 is electrically connected to the third diffusion preventing pattern 240. The third copper interconnection 260 includes the third via contact 260a electrically connected to the third diffusion preventing pattern 240 and the third trench contact 260b. The fourth barrier metal pattern 265 is formed between the third copper interconnection 260 and the fourth insulating interlayer 250, i.e., on bottom and side surfaces of the third copper interconnection 260.

Although not shown in FIGS. 2A to 2N, the copper interconnection may be formed in a multi-layered structure by repeatedly performing the processes as described in FIGS. 2F to 2J. Thus, the copper interconnection electrically connected to the semiconductor device may be formed without forming an opaque layer in an optical path of the photodetector 110.

In this embodiment, an interconnection structure having four multi-layers has been described, however, the interconnection structure may be a single-layer shown in FIG. 2E. Further, the interconnection structure may have N numbers of multi-layers, where N is a natural number greater than or equal to 2.

Referring to FIG. 2M, the fourth diffusion preventing pattern 270 is formed only on the third copper interconnection 260 in the same manner as the first diffusion preventing pattern 180 was formed on the lower copper interconnection 170 in FIG. 2F.

Then, the upper insulation layer 280 is formed on the fourth diffusion preventing pattern 270 and the fourth insulating interlayer 250 so as to insulate the fourth diffusion preventing pattern 270 from an upper structure formed thereon and to planarize a lower structure formed thereunder.

Referring to FIG. 2N, the color filter 300 is formed on the upper insulation layer 280. The color filter 300 may include an array structure, for example, having a red color filter, a green color filter and a blue color filter. In this embodiment, one of the red, green and blue color filters is formed on the upper insulation layer 280.

In order to focus light and provide the focused light to the photodetector 110, the lens 310 is formed on the color filter 300, thereby completing the CMOS image sensor. The lens 310 may be a substantially hemispherical convex lens.

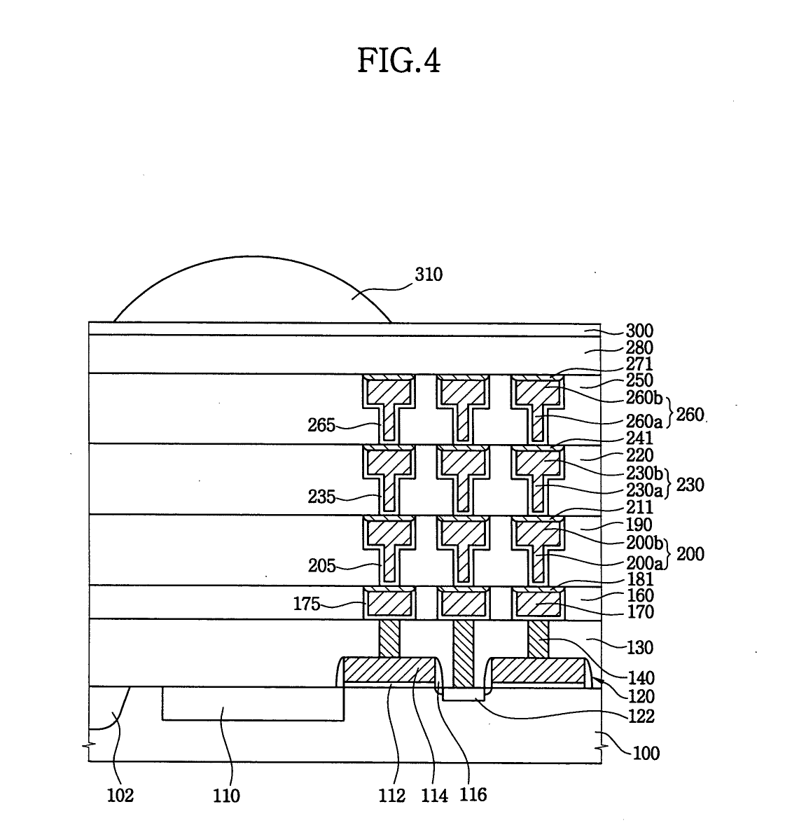

FIG. 4 illustrates a cross-section of an image sensor device according to a second embodiment of the present invention.

In the image sensor device according to the second embodiment, the upper surfaces of the copper interconnection and the barrier metal pattern are removed to a predetermined depth. Then, the diffusion preventing pattern is formed on the copper interconnection and the barrier metal pattern to fill the removed upper portions of the copper interconnection and the barrier metal pattern. The image sensor device according to this second embodiment has a substantially identical structure as described above regarding the first embodiment, except for a position of the diffusion preventing pattern and a method of forming the diffusion preventing pattern. That is, the above-described diffusion preventing pattern of the first embodiment may be formed by a selective deposition process. However, the diffusion preventing pattern of the second embodiment may be formed by a blanket deposition process. Thus, the diffusion preventing pattern of the first embodiment is positioned at a position higher than the insulating interlayer, whereas, an upper surface of the diffusion preventing pattern of the second embodiment is positioned to be substantially even with the insulating interlayer. In the second embodiment, identical reference numerals denote identical elements of FIG. 1, and thus detailed descriptions of identical elements will be omitted.

Referring to FIG. 4, the semiconductor substrate 100 includes an active region defined by the field oxide layer 102. The light-receiving device or photodetector 110, such as a photodiode, is formed on a surface of the active region of the semiconductor substrate 100. Further, transistors 120 serving as a switching device are formed on the semiconductor substrate 100. Each of the transistors 120 includes the gate electrode 114 and source/drain regions 122 formed between one gate electrode 114 and an adjacent gate electrode 114. The gate insulation layer 112 is formed under the gate electrode 114, and the spacer 116 is formed on a sidewall of the gate electrode 114.

The lower insulation layer 130 is formed on the semiconductor substrate 100 on which the transistors 120 are formed. The lower insulation layer 130 is formed with the lower contact 140 that is electrically connected to the source/drain regions 122 and the gate electrode 114 after passing through the lower insulation layer 130.

The plurality of insulating interlayers having at least one opening through which an upper surface of the lower contact 140 is exposed is formed on the lower insulation layer 130.

A plurality of copper interconnections and a plurality of diffusion preventing patterns are formed in the opening, and are electrically connected to the lower contact 140. That is, most of space of respective openings is filled with the copper interconnections, and remaining space of openings is filled with the diffusion preventing pattern. The diffusion preventing pattern formed on each of the copper interconnections prevents diffusion of copper into an adjacent insulating interlayer. The diffusion preventing pattern includes an opaque metal, and may serve as an etch stopper. The insulating interlayers and the copper interconnections will be described in detail below.

The first insulating interlayer 160 having the opening through which the lower contact 140 is exposed is formed on the lower insulation layer 130. The lower copper interconnection 170 is formed in the opening, and is electrically connected to the lower contact 140. The upper surface of the lower copper interconnection 170 is positioned at a position lower than that of the first insulating interlayer 160, so that the opening is not completely filled with the lower copper interconnection 170.

The first barrier metal pattern 175 is formed on a side surface and a lower surface of the opening before forming the lower copper interconnection 170, so as to prevent copper of the lower copper interconnection 170 from being diffused into the first insulating interlayer 160.

A first diffusion preventing pattern 181 is formed on the upper surface of the lower copper interconnection 170. The first diffusion preventing pattern 181 may include metal such as tungsten or tungsten nitride. The first diffusion preventing pattern 181 may have a thickness from about 100 Å to about 500 Å, preferably, from about 200 Å to about 300 Å.

The second insulating interlayer 190 is formed on the first insulating interlayer 160 and the first diffusion preventing pattern 181. The second insulating interlayer 190 includes the first via that exposes the lower copper interconnection 170 and the first trench formed over the first via. The first via contact 200a and the first trench contact 200b are formed in the first via and the first trench, respectively. The first via contact 200a and the first trench contact 200b may include copper. The first trench contact 200b is electrically connected to the first via contact 200a. The first via contact 200a and the first trench contact 200b will be referred to as the first copper interconnection 200.

The second barrier metal pattern 205 is formed between the first copper interconnection 200 and the second insulating interlayer 190, i.e., on bottom and side surfaces of the first copper interconnection 200, so as to prevent diffusion of copper in the first copper interconnection 200 into the second insulating interlayer 190.

A second diffusion preventing pattern 211 is formed on an upper surface of the first copper interconnection 200. The third insulating interlayer 220 is formed on the second diffusion preventing pattern 211 and the second insulating interlayer 190. The second insulating interlayer 220 includes the second via that partially exposes the second diffusion preventing pattern 211 and the second trench formed over the second via. The second via contact 230a and the second trench contact 230b are formed in the second via and the second trench, respectively. The second via contact 230a and the second trench contact 230b may include copper. The second trench contact 230b is electrically connected to the second via contact 230a. The second via contact 230a and the second trench contact 230b will be described as in a second copper interconnection 230.

The third barrier metal pattern 235 is formed between the second copper interconnection 230 and the third insulating interlayer 220, i.e., on bottom and side surfaces of the second copper interconnection 230, so as to prevent the diffusion of copper in the second copper interconnection 230 into the third insulating interlayer 220.

A third diffusion preventing pattern 241 is formed on the upper surface of the second copper interconnection 230. The fourth insulating interlayer 250 is formed on the third diffusion preventing pattern 241 and the third insulating interlayer 220. The fourth insulating interlayer 250 includes the third via that partially exposes the third diffusion preventing pattern 241 and the third trench formed over the third via. The third via contact 260a and the third trench contact 260b are formed in the third via and the third trench, respectively. The third via contact 260a and the third trench contact 260b may include copper. The third trench contact 260b is electrically connected to the third via contact 260a. The third via contact 260a and the third trench contact 260b will be referred to as in a third copper interconnection 260.

The fourth barrier metal pattern 265 is formed between the third copper interconnection 260 and the fourth insulating interlayer 250, i.e., on bottom and side surfaces of the third copper interconnection 260, so as to prevent diffusion of copper in the third copper interconnection 260 into the fourth insulating interlayer 250.

A fourth diffusion preventing pattern 271 is formed on the third copper interconnection 260. The upper insulation layer 280 is formed on the fourth insulating interlayer 250 and the fourth diffusion preventing pattern 271. The color filter 300 is formed on the upper insulation layer 280, and the lens 310 corresponding to the photodetector 110 is formed on the color filter 300 so as to focus light onto the photodetector 110.

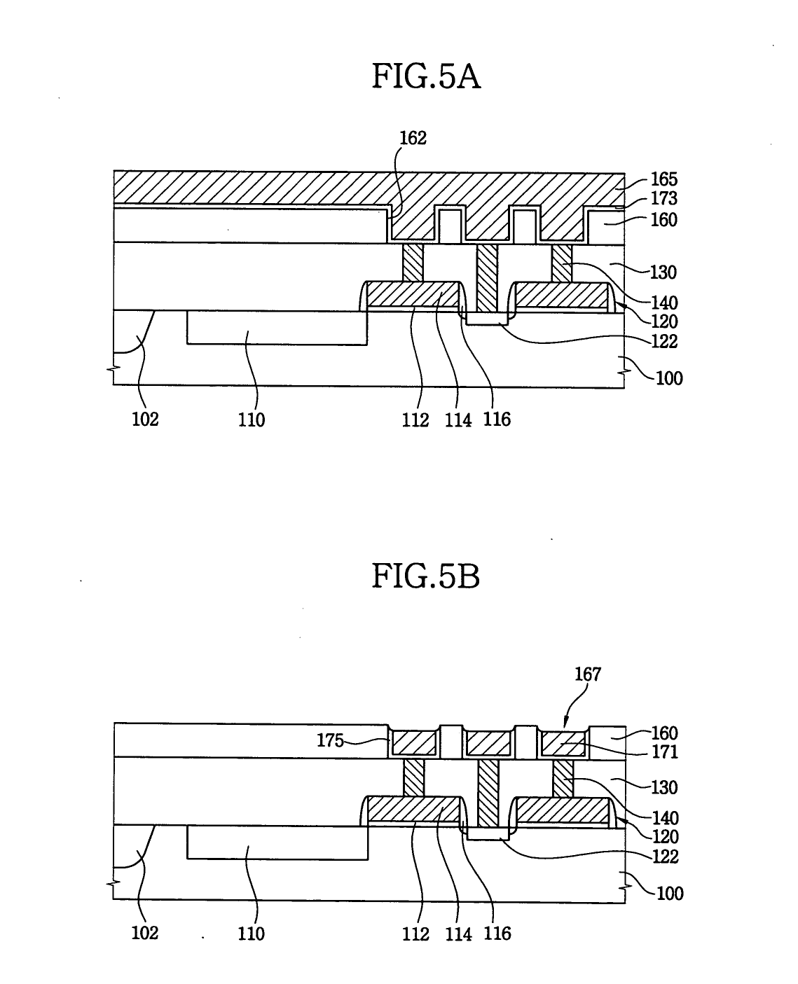

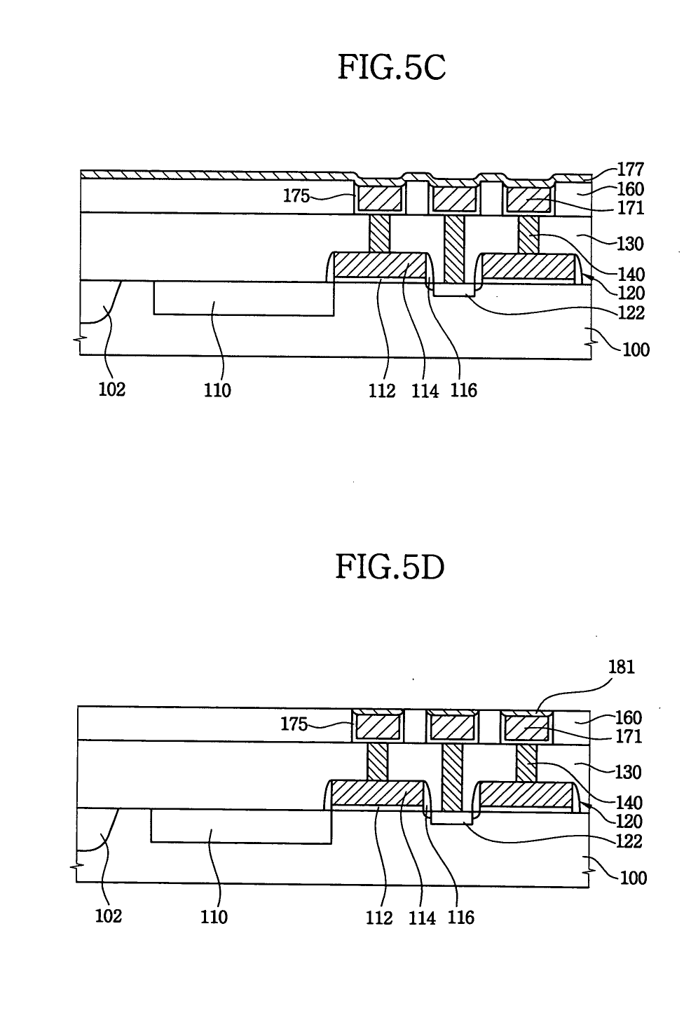

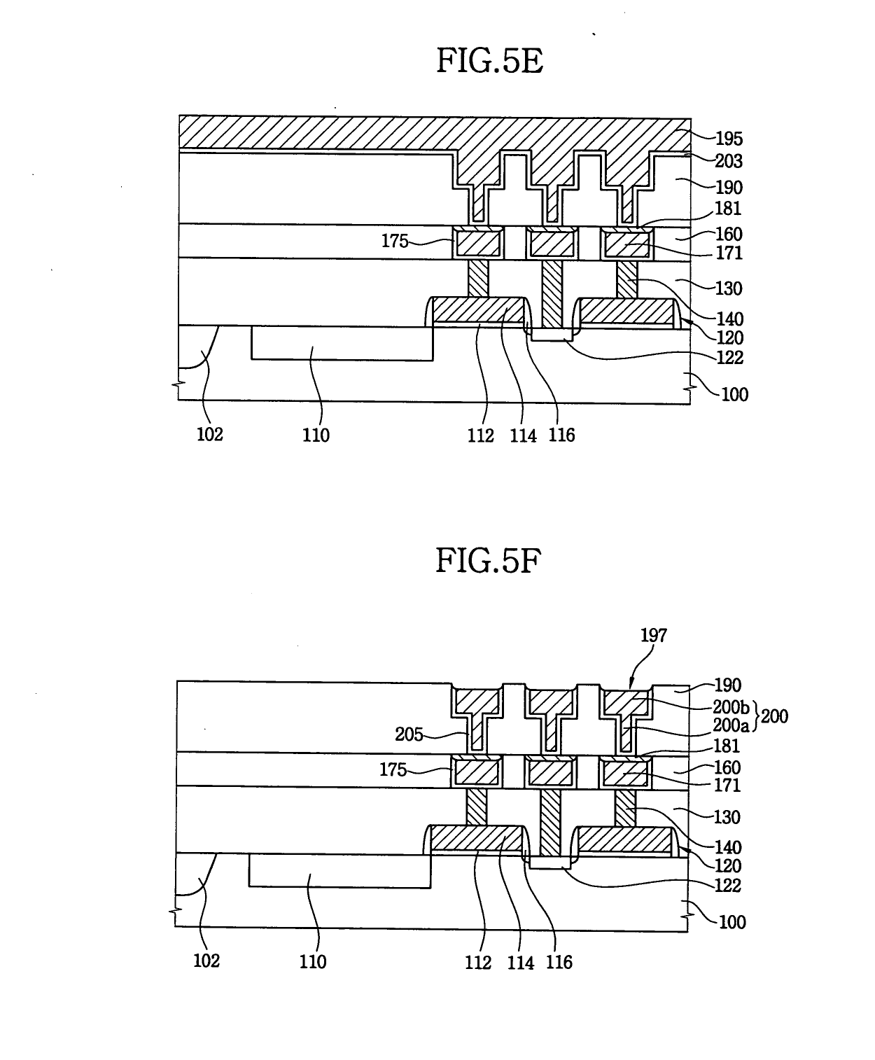

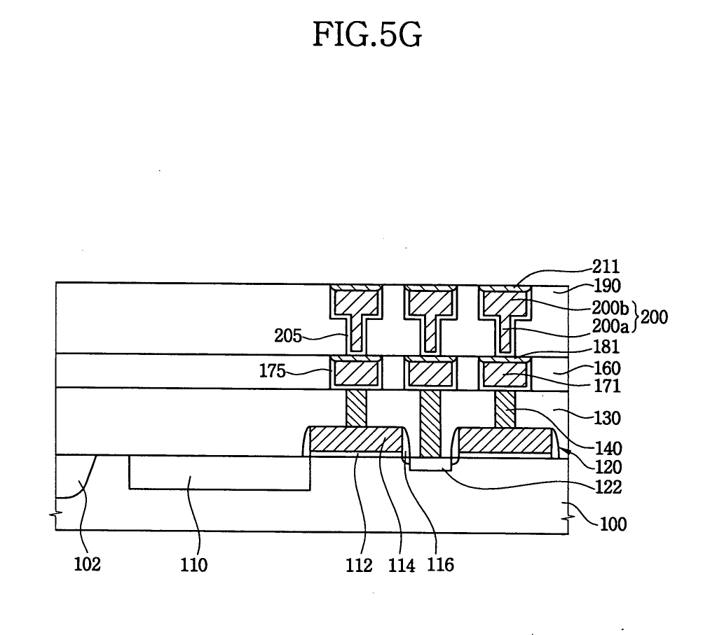

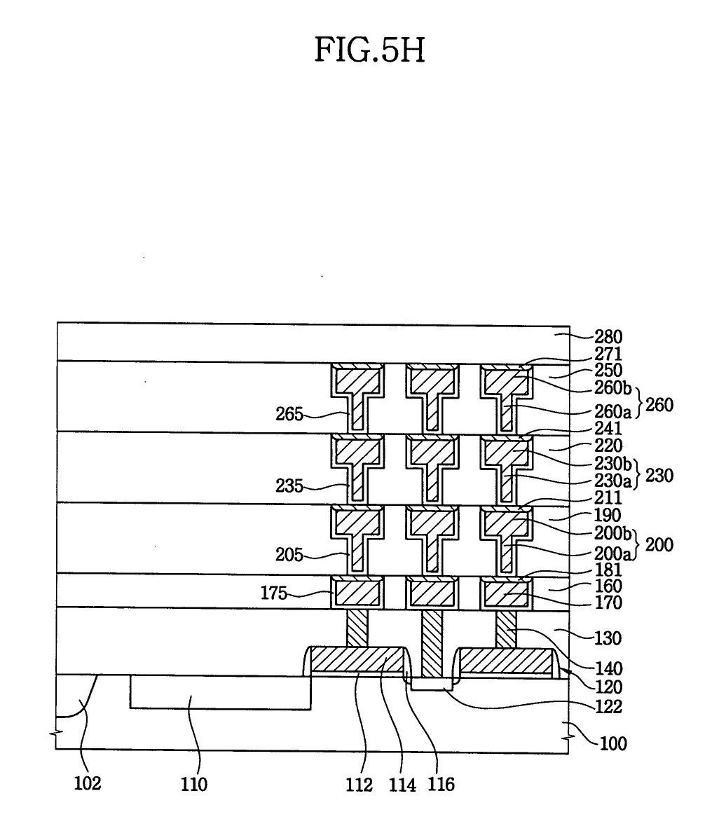

FIGS. 5A to 51 illustrate cross-sections of the image sensor device illustrated in FIG. 4 at various stages of formation for showing a method of manufacturing an image sensor device according to the second embodiment of the present invention. In FIGS. 5A to 5I, like reference numerals denote like elements in FIGS. 2A to 2N, and thus the detailed descriptions of thereof will be omitted.

Referring to FIG. 5A, the photodetector 110 is formed on the upper surface of the active region, and the transistors 120 are formed on the semiconductor substrate 100, such that the photodetector 110 is electrically connected to the transistors 120.

Then, the lower insulation layer 130 is formed over the semiconductor substrate 100 on which the transistors 120 are formed.

Contact holes exposing the upper surface of the source/drain regions 122 of the transistors 120 and the upper surface of the gate electrode 114 are formed through the lower insulation layer 130 by removing a portion of lower insulation layer 130, e.g., by etching using photolithography.

Metal, for example, titanium or tungsten, is formed on the lower insulation layer 130 to fill the contact holes 132, and then removed, e.g., using a chemical mechanical polishing (CMP) process, until the upper surface of the lower insulation layer 130 is exposed, thereby forming the lower contact 140 filling the contact holes 132.

Then, the first insulating interlayer 160 is formed on the lower contact 140 and the lower insulation layer 130. The first insulating interlayer 160 is partially removed, e.g., etched using photolithography, to form the lower trench 162 through which the upper surface of the lower contact 140 is exposed.

Subsequently, the first barrier metal layer 173 is formed along a profile of the lower trench 162 to cover the first insulating interlayer 160. The first copper layer 165 is formed on the first barrier metal layer 173 to fill the lower trench 162.

Referring to FIG. 5B, when the first copper layer 165 is removed, e.g., using CMP, so that the upper surface of the first insulating interlayer 160 is exposed, and a lower copper interconnection 171 is formed. The upper surface of the lower copper interconnection 171 is positioned at a position lower than the upper surface of the first insulating interlayer 160. The upper portion of the first copper layer 165 is removed, e.g., using CMP, until a predetermined depth is reached. Thus, a first recess 167 for a first diffusion preventing pattern is provided onto the lower copper interconnection 171.

A first diffusion preventing pattern is formed in the first recess 167. The depth of the first recess 167 may be from about 100 Å to about 500 Å, more preferably, from about 200 Å to about 300 Å.

Referring to FIG. 5C, a first diffusion preventing layer 177 is formed on the lower copper interconnection 171 and the first insulating interlayer 160. The first diffusion preventing layer 177 prevents the diffusion of the copper, and may serve as an etch stopper. To serve as an etch stop, the first diffusion preventing layer 177 includes metal whose etching selectivity is substantially less than that of the insulating interlayer. However, the first diffusion preventing layer 177 may not need to be formed only on the upper surface of the lower copper interconnection 171. Thus, the first diffusion preventing layer 177 may include metal such as tungsten or tungsten nitride, or insulating material such as silicon nitride. The first diffusion preventing layer 177 may have a thickness from about 100 Å to about 500 Å, more preferably, from about 200 Å to about 300 Å, which is substantially identical to or thicker than the depth of the first recess 167.

Referring to FIG. 5D, the first diffusion preventing layer 177 is planarized, e.g., by CMP, such that the first diffusion preventing layer 177 remains only in the first recess 167, thereby forming the first diffusion preventing pattern 181 on the lower copper interconnection 171. Thus, the opening is filled with the lower copper interconnection 171 and the first diffusion preventing pattern 181 formed on the lower copper interconnection 171.

Referring to FIG. 5E, the second insulating interlayer 190 is formed on the first diffusion preventing pattern 181 and the first insulating interlayer 160. The second insulating interlayer 190 is partially removed, e.g., etched using photolithography, to form the first primary via, so that the first diffusion preventing pattern 181 disposed under the first primary via is exposed through the first primary via. Then, the first trench and the first via are formed in the second insulating interlayer 190, e.g., etching using photolithography.

Although not shown in FIG. 5E, a process for removing the first diffusion preventing pattern 181 may be further performed. Particularly, when the first diffusion preventing pattern 181 includes metal, the first diffusion preventing pattern 181 exposed through the first via may not need to be removed. When the first diffusion preventing pattern 181 includes an insulating material, such as silicon nitride, however, the lower copper interconnection 171 must be exposed through the first via. For example, the insulating material of the first diffusion preventing pattern 181 may have a similar etch rate to that of the insulating interlayer and may be removed during the etching of the first primary via. In this embodiment, the first diffusion preventing pattern 181 includes metal, and the first diffusion preventing pattern 181 formed on the lower copper interconnection 171 is exposed through the first via.

Subsequently, the second barrier metal layer 203 is formed along a profile of the first trench and the first via to cover the second insulating interlayer 190. The second copper layer 195 is formed on the first barrier metal layer 203 to fill the first trench and the first via.

In this embodiment, a via-first damascene process that forms the first trench after the first via is formed has been described. However, a trench first damascene process forming the first via after the first trench is formed may be employed for the present invention.

Referring to FIG. 5F, the second copper layer 195 is removed, e.g., using CMP, so that the first copper interconnection 200 having the first via contact 200a electrically connected to the lower copper interconnection 171 and the first trench contact 200b is formed. The second barrier metal layer 203 also remains on the side surface and lower surface of the first trench and the first via so as to form the second barrier metal pattern 205 thereon. The upper portion of the first copper interconnection 200 is removed, e.g., using CMP, to a predetermined depth. Thus, the upper surface of the first copper interconnection 200 is positioned at a position lower than the upper surface of the second insulating interlayer 190, so that a second recess 197 for a second diffusion preventing pattern is formed on the first copper interconnection 200.

Referring to FIG. 5G, a second diffusion preventing layer (not shown) is formed on the first copper interconnection 200 and the second insulating interlayer 190. The second diffusion preventing layer is removed, e.g., etched by CMP, such that the second diffusion preventing layer remains only on the second recess 197, thereby forming the second diffusion preventing pattern 211 by the processes described in FIGS. 5C and 5D.

Referring to FIG. 5H, the third insulating interlayer 220 and the second copper interconnection 230 are successively formed by repeatedly performing the processes as described in FIGS. 5E to 5G. The second copper interconnection 230 also includes the second via contact 230a and the second trench contact 230b, and the third barrier metal pattern 235 is formed between the second copper interconnection 230 and the third insulating interlayer 220.

The third diffusion preventing pattern 241 is formed on the second copper interconnection 230. The fourth insulating interlayer 250 is formed on the third diffusion preventing pattern 241 and the third insulating interlayer 220, and the third copper interconnection 260 is formed in the fourth insulating interlayer 250. The third copper interconnection 260 also includes the third via contact 260a and the third trench contact 260b. The fourth barrier metal pattern 265 is formed between the third copper interconnection 260 and the fourth insulating interlayer 250. Then, the fourth diffusion preventing pattern 271 is formed on the third copper interconnection 260.

In this embodiment, the copper interconnection may be formed in a multi-layered structure by repeatedly performing the processes described in FIGS. 5E to 5G.

Subsequently, the upper insulation layer 280 is formed on the fourth diffusion preventing pattern 271 and the fourth insulating interlayer 250.

Referring to FIG. 51, the color filter 300 is formed on the upper insulation layer 280. In order to focus light onto the photodetector 110, the lens 310 is formed on the color filter 300, thereby completing the CMOS image sensor. The lens 310 may be a convex lens.

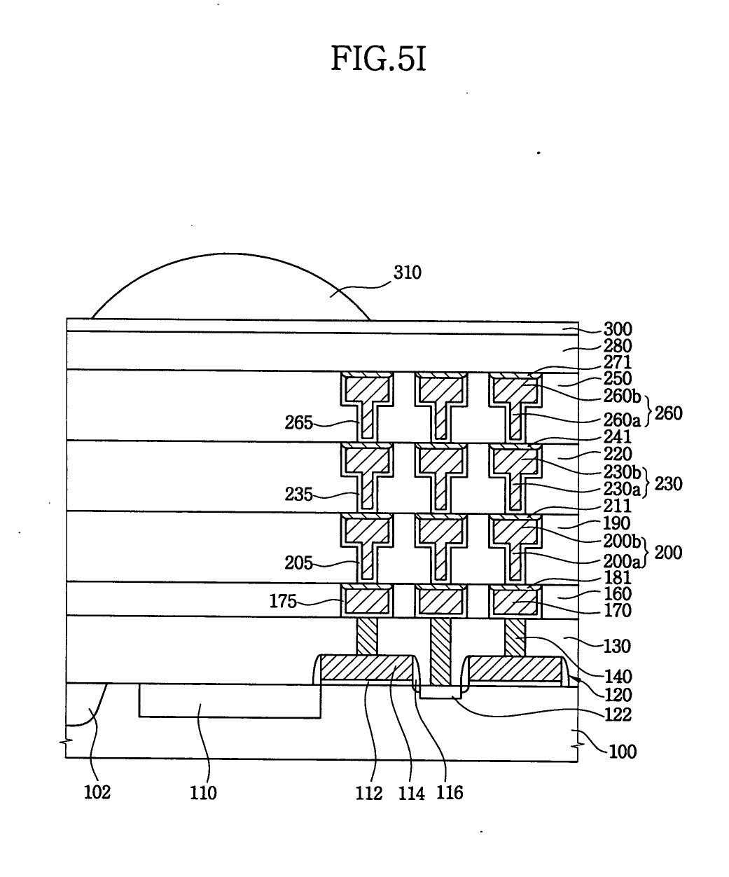

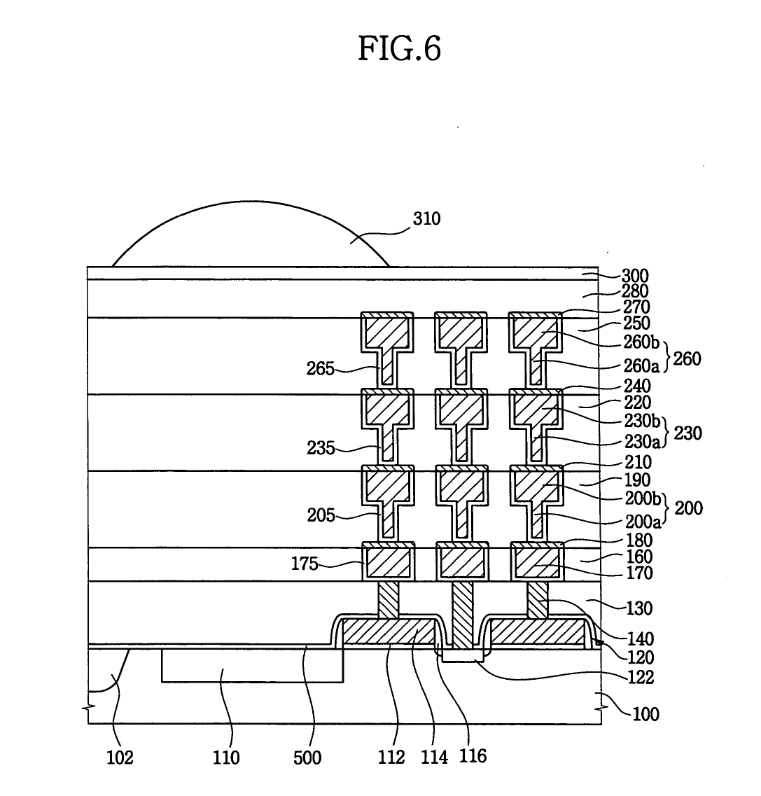

FIG. 6 illustrates a cross-section of an image sensor device according to a third embodiment of the present invention. The image sensor device according to this embodiment has a structure substantially identical to that of the first embodiment, but includes an anti-reflection coating on the photodetector. Thus, detailed descriptions of identical elements will be omitted.

Referring to FIG. 6, the image sensor device according to this embodiment includes an anti-reflection coating 500 formed over the semiconductor substrate 100 on which the photodetector 110 and the switching device 120 are formed. The anti-reflection coating 500 may increase the amount of light incident on the photodetector 110, thus improving performance of the image sensor device. The anti-reflection coating 500 may include SiON, SiC, SiCN, or SiCO. While the particular embodiment shown in FIG. 6 corresponds to that of FIG. 1, the anti-reflection coating 500 could obviously be used in connection with the embodiment shown in FIG. 4. Then, the image sensor device may be manufactured by performing the above-described processes.

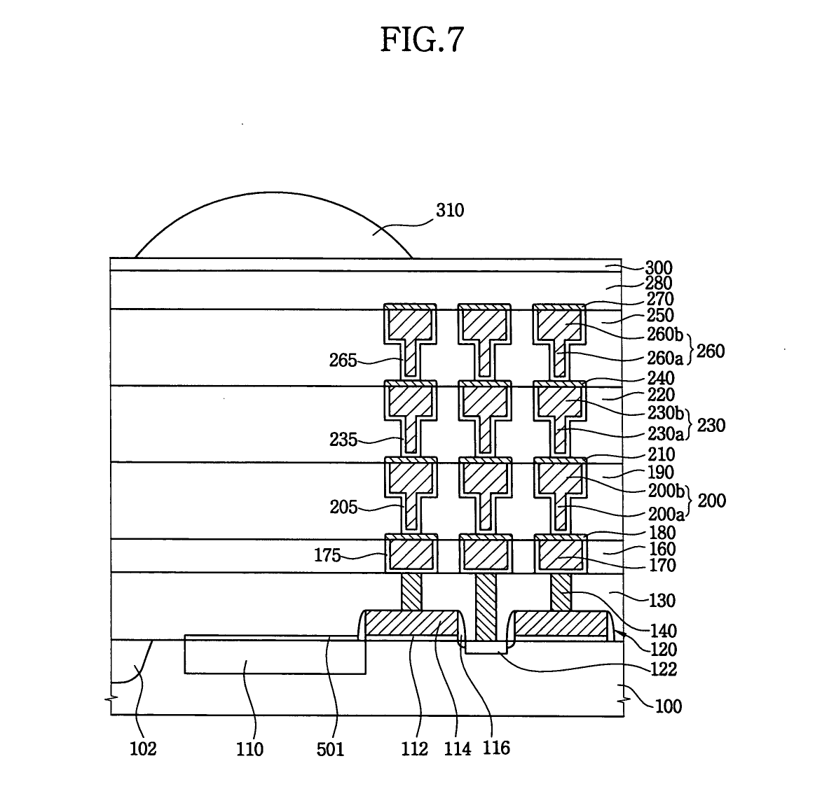

FIG. 7 illustrates a cross-section of an image sensor device according to a fourth embodiment of the present invention. The image sensor device according to this embodiment has a structure substantially identical to that of the above-described image sensor device except for a patterned anti-reflection coating formed on the photodetector. Thus, detailed descriptions of identical elements will be omitted.

Referring to FIG. 7, in the image sensor device according to this embodiment, an anti-reflection layer (not shown) is formed over the semiconductor substrate 100 on which the photodetector 110 and the switching device 120 are formed. The anti-reflection layer is patterned to cover the photodetector 110, thereby forming a patterned anti-reflection coating 501. The anti-reflection coating 501 may increase the amount of light incident on the photodetector 110, thus improving performance of the image sensor device. The anti-reflection coating 500 may include SiON, SiC, SiCN, or SiCO. While the particular embodiment shown in FIG. 6 corresponds to that of FIG. 1, the patterned anti-reflection coating 501 could obviously be used in connection with the embodiment shown in FIG. 4. Then, the image sensor device may be manufactured by performing the above-described processes.

According to the exemplary embodiments as described above, the multi-layered interconnections electrically connected to the transistors include copper having a low resistance, thereby minimizing problems, such as a low speed and a high resistance, under a process condition having a design rule of about 0.13 micrometer.

A diffusion preventing pattern that prevents diffusion of copper and may serve as an etch stopper is formed only on the copper interconnections. That is, the diffusion preventing pattern is not disposed on a position corresponding to the photodetector 110. Thus, the CMOS image sensor may have the superior light transmittance. Further, while copper is used as the electrically conductive material herein, the present invention may be used with any such material that diffuses undesirably into surrounding materials.

Having thus described exemplary embodiments of the present invention, it is to be understood that the invention defined by the appended claims is not to be limited by particular details set forth in the above description as many apparent variations thereof are possible without departing from the spirit or scope thereof as hereinafter claimed.

1. An image sensor device, comprising:
a substrate having a photodetector formed therein;
a semiconductor device on the substrate;
a transparent insulating interlayer on the substrate, the transparent insulating interlayer having at least one opening formed therethrough corresponding to the semiconductor device;
an electrically conductive pattern filling the opening;
a diffusion preventing pattern selectively formed only on the electrically conductive pattern;
a color filter provided in an optical path of the photodetector; and
a lens formed on the color filter.

2. The image sensor device as claimed in claim 1, wherein the electrically conductive pattern comprises:
a via contact including copper; and
a trench contact including copper, the trench contact making contact with an upper surface of the via contact.

3. The image sensor device as claimed in claim 1, further comprising:
a lower insulation layer between the insulating interlayer and the substrate, the lower insulation layer covering the semiconductor device; and
a lower contact formed at a predetermined portion of the lower insulation layer to electrically contact with the semiconductor device.

4. The image sensor device as claimed in claim 3, further comprising:
a first insulating interlayer disposed on the lower insulation layer;
a first copper interconnection formed at a predetermined portion of the first insulating interlayer to electrically contact with the lower contact; and
a first diffusion preventing pattern formed on the first copper interconnection.

5. The image sensor device as claimed in claim 4, further comprising:
a first barrier metal layer formed on a lower surface and a side surface of the first copper interconnection so as to prevent copper of the first copper interconnection from diffusing into the first insulating interlayer.

6. The image sensor device as claimed in claim 4, further comprising:
a second insulating interlayer to an N-th insulating interlayer disposed on the first insulating interlayer, where N is a natural number greater than or equal to 2;
a first copper interconnection to an (N−1)-th copper interconnection formed at each of predetermined portions of the second insulating interlayer to the N-th insulating interlayer; and
a diffusion preventing pattern selectively formed on each of the first copper interconnection to the (N−1)-th copper interconnection.

7. The image sensor device as claimed in claim 6, each first copper interconnection to the (N−1)-th copper interconnection comprising:
a via contact including copper; and
a trench contact including copper, the trench contact electrically contacting an upper surface of the via contact.

8. The image sensor device as claimed in claim 6, further comprising:
a second barrier metal layer to an N-th barrier metal layer formed on lower surfaces and side surfaces of the first copper interconnection to the (N−1)-th copper interconnection, respectively, the second barrier metal layer to the N-th barrier metal layer preventing copper from being diffused from the first copper interconnection to the (N−1)-th copper interconnection into the second insulating interlayer to the N-th insulating interlayer, respectively.

9. The image sensor device as claimed in claim 1, further comprising:
an anti-reflection coating on at least the photodetector.

10. The image sensor device as claimed in claim 1, wherein the electrically conductive pattern completely fills the opening, the diffusion preventing pattern is formed on an upper surface of the electrically conductive pattern, and the upper surface of the electrically conductive pattern has a height substantially identical to that of an upper surface of the insulating interlayer.

11. The image sensor device as claimed in claim 1, wherein the electrically conductive pattern fills a lower portion of the opening and the diffusion preventing pattern fills an upper portion of the opening, thereby completely filling the opening with the electrically conductive pattern and the diffusion preventing pattern.

12. The image sensor device as claimed in claim 1, wherein the diffusion preventing pattern is a metal.

13. The image sensor device as claimed in claim 1, wherein the diffusion preventing pattern is formed by selectively forming a metal on the metal pattern by an electroless plating process.

14. The image sensor device as claimed in claim 1, wherein the diffusion preventing pattern is formed by selectively forming a metal on the metal pattern by a chemical vapor deposition process.

15. The image sensor device as claimed in claim 1, wherein the diffusion preventing pattern includes tungsten.

16. The image sensor device as claimed in claim 1, wherein the diffusion preventing pattern includes silicon nitride or tungsten nitride.

17. The image sensor device as claimed in claim 1, wherein the diffusion preventing pattern has a thickness of about 100 Å to about 500 Å.

18. The image sensor device as claimed in claim 1, wherein the electrically conductive material is copper.

19. The image sensor device as claimed in claim 1, further comprising an upper insulation layer formed over the transparent insulating interlayer, the upper insulation layer for covering the diffusion preventing pattern.

20. The image sensor device as claimed in claim 19, wherein the color filter is formed on the upper insulation layer.

21. An image sensor device, comprising:
a substrate on which a photo diode and a semiconductor device are formed;
a lower insulation layer formed over the substrate, the lower insulation layer having a lower contact electrically connected to the semiconductor device;
an insulating interlayer that is transparent and formed on the lower insulation layer, the insulating interlayer having at least one opening formed therethrough;
a copper pattern filling the opening so as to transmit a signal;
a diffusion preventing pattern selectively formed only on the copper pattern so as to prevent diffusion of copper in the copper pattern;
an upper insulation layer formed over the insulating interlayer to cover the diffusion preventing pattern;
a color filter formed on the upper insulation layer; and
a microlens formed on the color filter.

22. The image sensor device as claimed in claim 21, wherein the copper pattern comprises:
a via contact; and
a copper wiring electrically contacting with an upper surface of the via contact.

23. The image sensor device as claimed in claim 21, further comprising:
a first insulating interlayer disposed on the lower insulation layer;
a first copper wiring formed at a predetermined portion of the first insulating interlayer to contact with the lower contact; and
a first diffusion preventing pattern formed on the first copper wiring.

24. The image sensor device as claimed in claim 23, further comprising:
a first barrier metal layer formed on a lower surface and a side surface of the first copper wiring so as to prevent copper from being diffused into the first insulating interlayer.

25. The image sensor device as claimed in claim 23, further comprising:
a second insulating interlayer to an N-th insulating interlayer disposed on the first insulating interlayer, where N is a natural number greater than or equal to 2;
a first metal layer to an N-th metal layer formed at each of predetermined portions of the second insulating interlayer to the N-th insulating interlayer, each of the first metal layer to the N-th metal layer having a via contact comprising copper and a copper wiring electrically contacting with an upper surface of the via contact; and
a diffusion preventing pattern selectively formed on each of the first metal layer to the N-th metal layer.

26. The image sensor device as claimed in claim 25, further comprising:
a second barrier metal layer to an N-th barrier metal layer formed on lower surfaces and side surfaces of the first metal layer to the N-th metal layer, respectively, so as to prevent copper from being diffused into the second insulating interlayer to the N-th insulating interlayer.

27. The image sensor device as claimed in claim 21, further comprising:
a reflection preventing layer or a reflection preventing pattern disposed on the photo diode so as to enhance light absorbance of the photo diode.

28. The image sensor device as claimed in claim 21, wherein the copper pattern completely fills the opening, and the diffusion preventing pattern is formed on an upper surface of the metal pattern, and wherein the upper surface of the metal pattern has a height substantially identical to that of an upper surface of the insulating interlayer.

29. The image sensor device as claimed in claim 21, wherein the copper pattern fills a lower portion of the opening and the diffusion preventing pattern fills an upper portion of the opening, thereby completely filling the opening by the copper pattern and the diffusion preventing pattern.

30. The image sensor device as claimed in claim 21, wherein the diffusion preventing pattern is formed by selectively forming a metal on the copper pattern by an electroless plating process.

31. The image sensor device as claimed in claim 21, wherein the diffusion preventing pattern is formed by selectively forming a metal on the copper pattern by a chemical vapor deposition process.

32. The image sensor device as claimed in claim 31, wherein the diffusion preventing pattern comprises tungsten.

33. The image sensor device as claimed in claim 21, wherein the diffusion preventing pattern comprises silicon nitride or tungsten nitride.

34. The image sensor device as claimed in claim 21, wherein the diffusion preventing pattern has a thickness from about 100 Å to about 500 Å.
